(19) United States
(12) Patent Application Publication
(10) Pub. No.: US 2011/0260219 A1
(43) Pub. Date: Oct. 27, 2011

(54) PROTECTIVE LAYERS SUITABLE FOR EXHAUST GASES FOR HIGH-TEMPERATURE CHEMFET EXHAUST GAS SENSORS

(76) Inventors: Thomas Wahl, Pforzheim (DE); Oliver Wolst, Singapore (SG); Alexander Martin, Regensburg (DE)

(21) Appl. No.: 12/998,079

(22) PCT Filed: Jul. 16, 2009
(86) PCT No.: PCT/EP2009/059118

§ 371 Date: Jun. 29, 2011

(30) Foreign Application Priority Data
Sep. 16, 2008 (DE) 102008042139.1

(51) Int. Cl. H01L 29/772; H01L 21/56

(52) U.S. Cl. 257/253; 438/49; 257/E21.502; 257/E29.242

(57) ABSTRACT

In a method for producing a sensor element including at least one sensitive component, a masking layer made of a material which is thermally decomposable without residue is applied to the sensitive component, the sensitive component being essentially covered by the masking layer, a protective layer made of a temperature-stable material is applied to the masking layer, and the masking layer is removed by pyrolysis or a low-temperature-guided oxygen plasma. The resulting sensor element includes at least one sensitive component covered by a protective layer made of a temperature-stable material, the sensitive component and the protective layer being placed at a distance from each other.

### BACKGROUND OF THE INVENTION

1. Field of the Invention

The present invention relates to a method for producing a sensor element including at least one sensitive component.

2. Description of Related Art

Sensor elements that include a sensitive component are used, for example, to measure at least one property of a gas in a measuring gas chamber. This at least one property may be a physical and/or chemical property of the gas, in particular a composition of the gas. Thus such a sensor element may be used, for example, for measuring a concentration and/or a partial pressure of a particular gas component in the gas, for example in the exhaust gas of an internal combustion engine, or to show the presence of these gas components qualitatively and/or quantitatively. Instead of or in addition to a gas component, however, it is also possible, for example, to show the presence of other types of analytes, for example analytes in other aggregate states than the gaseous state, for example liquid analytes and/or analyte particles.

In order to determine at least one property of a gas in a measuring gas chamber, the sensor elements include in general a component having a gas-sensitive layer, in particular a semiconductor component having a gas-sensitive layer. Such semiconductor components having a gas-sensitive layer are generally gas-sensitive field-effect transistors. In such gas-sensitive field-effect transistors, the gate electrode is provided with a coating that is able to adsorb gas molecules, which result in a potential change at the gate, which in turn changes the charge carrier density in the transistor channel and hence the characteristic curve of the transistor. This is a signal for the presence of the particular gas. A material is chosen for the coating in each case which is selective for certain gases that are to be detected. To this end, the coating generally contains a catalytically active material. By using different gas-sensitive field-effect transistors, each of which has specific gate coatings, it is possible to detect different gases.

The gases to be detected may interact in various ways with the sensor element, in particular with the gas-sensitive layer, for example through adsorption and/or chemical sorption, chemical reactions, or in some other manner. The interaction of the gas being detected using the gas-sensitive layer results in the potential change at the gate, which influences the charge carrier density in the underlying channel area. The potential change at the gate is brought about by the changed work function of the gate metal vis-à-vis the gate dielectric, and/or the change in the interface state density between dielectric (insulator) and semiconductor material. The characteristic curve of the transistor is changed thereby, which may be taken as a signal for the presence of the particular gas. Examples of such gas-sensitive field-effect transistors are depicted for example in published German patent application document DE 26 10 530, so that that publication may be referred to for possible structures of such gas-sensitive field-effect transistors.

Sensor elements for detecting gas components are also used for example in exhaust tracts of motor vehicles. Using such sensor elements, it is possible for example to determine the presence of nitrogen oxides, ammonia or hydrocarbons in the exhaust gas. However, heavy demands are placed on the sensor elements because of the high temperatures of the exhaust gas from the internal combustion engine. In addition, there may also be particles, for example contained in the exhaust, which may result in abrasion of the gate coatings. This makes it necessary to protect the gate coatings; the function must not be impaired by such protection, however.

To protect the gate coatings, it is known, for example, to apply a gas-sensitive coating to the gas-sensitive field-effect transistor. One such gas-sensitive field-effect transistor having an open-pore porous sensitive layer is described for example in published German patent application document DE A 10 2005 008 051. However, applying a porous layer to the gas-sensitive field-effect transistor has the disadvantage that the very sensitive gate coating may be damaged. Furthermore, it is possible, in particular when using the sensor element at high temperatures, that stresses may arise due to differing coefficients of thermal expansion of the semiconductor component and the protective layer, which may result in cracks in the protective layer or even peeling of the protective layer, in particular in the case of coating thicknesses of some micrometers to a few millimeters.

### BRIEF SUMMARY OF THE INVENTION

One method according to the present invention for producing a sensor element including at least one sensitive component includes the following steps:

(a) applying a masking layer of a material which is thermally decomposable without residue to the sensitive component, the sensitive component being completely covered by the masking layer,
(b) applying a protective layer of a temperature-stable material to the masking layer,
(c) removing the masking layer by pyrolysis or a low-temperature-guided oxygen plasma.

By removing the masking layer after applying the protective layer, a cavity is produced between the sensitive component and the protective layer. The protective layer does not lie directly on the sensitive component. This has the advantage in particular that thermal stresses are prevented under high temperature loads and temperature changes when there are great differences in the coefficients of thermal expansion of the protective layer and the sensitive component. At the same time, this results in stabilizing the protective layer, since no cracks develop in the protective layer and no peeling of the protective layer occurs when the protective layer and the sensitive component expand differently due to high temperature loads and temperature change.

In general, the sensitive component is applied to a carrier substrate. The carrier substrate usually includes conductor paths with which the sensitive component makes contact. In particular when the sensor element is used at high temperatures, the carrier substrate is made of a ceramic material. However, when used in low-temperature applications it is also possible that the carrier substrate is, for example, a polymer carrier substrate, such as is used generally in the production of printed circuit boards.

If the sensor element is used in high-temperature applications, however, for example for analyzing exhaust gases from internal combustion engines, the material from which the carrier substrate is made is a ceramic. Examples of suitable ceramic materials for producing the carrier substrate are silicon nitride (Si₃N₄), silicon oxide, (SiO₂), aluminum oxide (Al₂O₃) or zirconium oxide (ZrO), or mixtures of two or more of these materials. To achieve protection of the sensitive component, it is necessary that the sensitive component be enclosed on all sides. In order to implement appropriate protection, the protective layer is bonded to the carrier substrate. To prevent the occurrence of thermal stresses due to differing coefficients of thermal expansion of the material of the protective layer and the material of the carrier substrate, which could result in damage to the protective layer, for example breaking of the protective layer, it is preferred that the material for the protective layer be the same as the material for the carrier substrate.

The temperature-stable material for the protective layer is thus preferably a ceramic material, in particular preferably silicon nitride, silicon oxide, aluminum oxide, zirconium oxide or mixtures thereof.

The material which is thermally decomposable without residue of which the masking layer is made is preferably a thermally decomposable polymer. Examples of materials or material classes of suitable thermally decomposable polymers which may be used as the masking layer are polyesters, polyethers such as polyethylene glycol, polypropylene glycol, polyethylene oxide or polypropylene oxide. Also suitable are polyacrylates, polyacetates, polyketals, polycarbonates, polyurethanes, polyetherketones, cycloaliphatic polymers, aliphatic polyamides, polyvinyl phenols and epoxy compounds. Co-polymers or ter-polymers of the material classes named here are also suitable.

Preferably, the decomposable material is photosensitive or photostructurable, such as a resist, for example.

In particular, a photostructurable resist may be one of the following combinations of a basic polymer and a photoactive component. For example, polyacrylates, polymethacrylates, polyacetates, polyacetals, co-polymers with maleic anhydride, aliphatic, aromatic, or cycloaliphatic polymers with tert-butyl ester (COOC(CₙH₂ₙ₊₁)₃ where n=1, 2, 3) such as, for example, tert-butyl methacrylate, or with tert-butoxycarbonyloxy groups (OCOO(CₙH₂ₙ₊₁)₃) such as tert-butoxycarbonyloxystyrol, may be used as the basic polymer. Examples of suitable photoactive components are, for example, diazoketones, diazoquinones, triphenylsulfonium salts or diphenyliodionium salts. Thus the resist may be structured, for example using lithography and etching processes. Examples of suitable solvents for obtaining applicable polymeric solutions or mixtures of a basic polymer and a photoactive component are methoxypropylacetate, ethoxypropylacetate, ethoxyethylpropionate, N-methylpyrrolidon, γ-butyrolactone, cyclohexanone, cyclopentanone or ethyl acetate.

The layer thickness with which the material which is thermally decomposable without residue for the masking layer is applied to the sensitive component is preferably in the range from 1 μm to 2 mm. Because of the small thickness of the masking layer, it is possible in particular to implement a compact structure. The masking has the further advantage that in the subsequent process of applying the ceramic protective layer, the sensitive semiconductor component having mechanically sensitive electrodes is protected, and abrasion of the electrode materials which sometimes occurs during the production of the protective layer is avoided. Furthermore, the thermally decomposable material may be decomposed already during the application process, for example during thermal plasma spraying, and thus may act as a pore former. If the coating procedure takes place at temperatures below the decomposition point of the masking layer, the protective layer is preferably designed in such a way that it is already permeable to decomposable material.

Since the sensitive component has a three-dimensional structure, to apply the masking layer of the material which is thermally decomposable without residue it is necessary to use a method that is 3D-capable, i.e., one in which coating over at least one step is possible. Examples of suitable methods for applying the material which is thermally decomposable without residue are dispensing, ink-jet printing, pad printing, spin coating, or dipping. Dispensing, ink-jet printing, and pad printing have the additional advantage that additive application is possible in order to produce the desired layer thickness. In order to apply the material which is thermally decomposable without residue to the sensitive component using one of the methods named above, the polymer used for the layer is, for example, dissolved or dispersed in a solvent. The application of the material which is thermally decomposable without residue is followed in this case by a drying step, in order to remove the solvent from the thermally decomposable material, in particular the polymer.

Besides the use of polymers which are dissolved or dispersed in a solvent, it is also possible alternatively to use, for example, monomers and/or polymers having radiation-hardening properties, in particular UV-curing properties, to form the masking layer. In this case, after the application of the monomers and/or polymers for the masking layer, a light-exposure step is performed whereby the monomers and/or polymers cross-link and thus cure into a rigid, generally insoluble polymer layer. Suitable monomers and/or polymers having radiation-hardening properties are, for example, ones which contain epoxy groups, acrylate groups and/or methacrylate groups as functional groups.

After the drying, that is, the removal of solvent, and/or the curing, for example by a light-exposure step, the protective layer of the temperature-stable material is applied to the masking layer. A spraying process is usually used as the application method to apply the protective layer. Various spraying processes are conceivable and advantageously useable to produce a thick, abrasion-resistant protective layer. Preferred are plasma spraying processes, using which the protective layer of the temperature-stable material is applied to the masking layer. The masking layer prevents an uncontrolled effect of the plasma on the gas-sensitive layer during the plasma spraying process, which results in a more robust design of the process of producing the protective layer, and thus in a cost reduction. The effect of the plasma during the plasma spraying process is manifested, for example, in a mechanical stress on the sensitive component during the application.

An advantage of using a plasma spraying method is that a defined porosity of the protective layer may be set. The porosity of the protective layer is necessary so that the gas being detected or the gas mixture being analyzed passes through the protective layer and reaches the gas-sensitive component. However, particles contained in the gas stream are kept away from the sensitive component by the protective layer, so that mechanical damage to the sensitive component is prevented.

After the protective layer is applied, the masking layer is removed by pyrolysis or a low-temperature-guided oxygen plasma. The gaseous product that develops in the pyrolysis or the low-temperature-guided oxygen plasma may be removed through the pores of the porous protective layer. Furthermore, it is also possible to adjust the porosity of the protective layer through the pyrolysis or the low-temperature-guided oxygen plasma. In particular, in the case of a protective layer of a ceramic material it is further preferred that the protective layer be sintered during the pyrolysis or by the low-temperature-guided oxygen plasma. Porous sintering is usually done here, in order to adjust the porosity of the protective layer.

The pyrolysis to remove the masking layer may be carried out, for example, in air or in an oxygen-rich atmosphere. It is also possible to change the composition of the atmosphere during the pyrolysis. The oxygen-rich air used is, for example, pure oxygen or oxygen-enriched air. In the case of oxygen-enriched air, the proportion of oxygen in the atmosphere is preferably in the range from 21% to 100% by volume, in particular in the range from 22% to 50% by volume. Moreover, pyrolysis in a hydrogen-rich atmosphere is also possible. The requisite decomposition temperature is dependent above all on the choice of the thermally, decomposable masking materials. However, the temperature may be influenced through the pyrolysis parameters, for example the ambient pressure.

A sensor element designed according to the present invention, which is produced, for example, by the method described above, includes at least one sensitive component and a protective layer of a temperature-stable material, the sensitive component being covered by the protective layer of the temperature-stable material. The sensitive component and the protective layer are separated from each other. As described above, because the sensitive component and the protective layer are separated from each other, thermal stresses due to high-temperature loads or in the case of temperature changes are avoided.

The sensitive component is preferably a semiconductor sensor element, in particular a semiconductor sensor element having a semiconductor material that includes silicon carbide and/or gallium nitride. The sensitive component may include in particular a field-effect transistor or a sensor element that is based on a field-effect transistor. By particular preference, the sensitive component is a chemosensitive field-effect transistor, in particular a gas-sensitive field-effect transistor.

A sensor component has, for example, a sensor body having at least one sensor surface that is accessible to the gas being measured. The sensor surface is usually designed in such a way that at least one property of the gas is measurable with the sensor surface. In particular, it should be possible with the sensor surface to determine selectively a concentration of at least one gas component in the gas being measured, quantitatively and/or qualitatively. To this end it is possible, for example, that the sensor surface includes a semiconductor surface of an inorganic semiconductor material, which in addition may possibly be provided with a sensitive coating. For example, a sensitive coating may be included which increases the selectivity of detection of a particular gas component. The sensor surface may be, for example, a gate surface of a transistor element, in particular of a field-effect transistor. Preferably, the sensor surface is situated on an external surface of the sensor body, for example on an external surface of an inorganic semiconductor layer structure, in particular a semiconductor chip.

The gas-sensitive layer generally contains a catalytically active material, so that upon contact with the gas being measured a chemical reaction is initiated, whereby the electrical property of the gas-sensitive layer changes.

In order to enable access of the gas being measured to the gas-sensitive surface, the protective layer of the temperature-stable material is porous. The protective layer preferably has a porosity in the range from 2% to 50%, in particular in the range from 10% to 30%.

### BRIEF DESCRIPTION OF THE DRAWINGS

FIGS. 1-4 show procedural steps to produce a sensor element according to the present invention, based on the example of a gas-sensitive field-effect transistor.

### DETAILED DESCRIPTION OF THE INVENTION

FIG. 1 depicts a sensor element still without a coating. A sensor element 1 includes a sensitive component 3 which is connected to a carrier substrate 5.

In the specific embodiment depicted here, sensitive component 3 is a gas-sensitive field-effect transistor. As an alternative to the specific embodiment depicted here having one field-effect transistor as the sensitive component 3, it is also possible to use a plurality of field-effect transistors 3, for example in the form of an array of gas-sensitive field-effect transistors. An array of gas-sensitive field-effect transistors is used, for example, to detect different gas components simultaneously. Sensor element 1 may serve, for example, to identify one or more gas components of a gas in a gaseous environment qualitatively and/or quantitatively. The gaseous environment may be, for example, an exhaust tract of an internal combustion engine.

Sensitive component 3, in the form of a gas-sensitive field-effect transistor, includes a sensor body 7, which is formed, for example, completely or partially of silicon carbide (SiC) and/or gallium nitride (GaN) as the semiconductor material, possibly in various doping concentrations. Sensor body 7 is usually constructed as a semiconductor chip. In general, sensor body 7 includes a source area 9 and a drain area 11, which may be produced, for example, by appropriate doping concentrations in sensor body 7. For example, sensor body 7 has n doping in source area 9 and drain area 11, whereas the remainder of sensor body 7 may be p doped. For electrical triggering, source area 9 is connected to a source electrode 13 and drain area 11 to a drain electrode 15. The electrical contacting of source electrode 13 or of drain electrode 15 is accomplished through contacting means 17. As contacting means 17, conductor path structures may be printed for example on sensitive component 3, which connect source electrode 13 or drain electrode 15 with conductor paths 19 on carrier substrate 5. Alternatively, however, it is also possible to use, for example, wiring in the form of wire bonds, or any other contacting that is known to those skilled in the art, as contacting means 17 to connect source electrode 13 or drain electrode 15 to conductor paths 19. Moreover, in a specific embodiment a flip-chip structure is also conceivable. The sensor surface having gas-sensitive coating 25 points toward ceramic carrier 5, gas access being ensured via an additional channel in carrier 5.

When sensor element 1 is electrically triggered, a current channel forms between source area 9 and drain area 11 in sensor body 7. When conventional field-effect transistors are used, the extent and the electrical properties of this current channel, and hence a current flow between source area 9 and drain area 11, are influenced by a gate electrode 21. When a gas-sensitive field-effect transistor is used, the role of gate electrode 21 is assumed on the one hand by a metal electrode in combination with a semiconductor oxide material, or on the other hand, for example, by a gate layer stack 23, which is provided with a gas-sensitive coating 25. The gate layer stack is usually made of a dielectric material, for example SiO₂, Si₃N₄, SiOₓN_{y}, Al₂O₃, HfO₂, ZrO₂ and mixtures thereof. Any gate layer stack known to those skilled in the art, such as is used for gas-sensitive field-effect transistors according to the related art, is suitable as gate layer stack 23.

Gas-sensitive coating 25 usually serves to selectively adsorb, absorb, or chemisorb gas molecules or other analytes which are to be detected, or to trigger chemical reactions with these analytes. The presence of the analyte to be detected, for example the gas molecules of the gas component to be detected, in the gas being analyzed, thus determines the electrical properties of gate electrode 21, and thus the position, the extent, and the other electrical properties in the current channel between source area 9 and drain area 11. The current flow between source area 9 and drain area 11 is thus influenced by the presence or absence of the analyte to be detected.

Besides the specific embodiment depicted here, having a gate layer stack 23 to which gas-sensitive coating 25 is applied, it is, however, alternatively also possible for gas-sensitive coating 25 to be applied directly to a surface 27 of sensor body 7. A gate layer stack 23 is usually used, however.

Source electrode 13 and drain electrode 15 are usually ohmic contacts which are made of a highly conductive material. Metals, for example tantalum, tantalum silicide, chromium, titanium, nickel, aluminum, titanium nitride, platinum, silicides, gold or every possible sequence of layers are normally used as materials for source electrode 13 and drain electrode 15.

In order to protect source electrode 13, drain electrode 15, gate layer stack 23 and sensor body 7 from aggressive media in the gas being analyzed, a passivation layer 29 is preferably applied to sensor body 7, source electrode 13 and drain electrode 15. Passivation layer 29 may be dispensed with if sensor element 1 is used in non-aggressive media. Ceramic materials, for example silicon nitride (Si₃N₄), silicon oxide (SiO₂), aluminum oxide (Al₂O₃), titanium dioxide (TiO₂) and mixtures thereof are usually used as the material for passivation layer 29. One preferred mixture is a mixture of silicon nitride and silicon oxide. However, in order not to impair the gas-sensitive property of sensitive component 3, passivation layer 29 does not cover gas-sensitive coating 25.

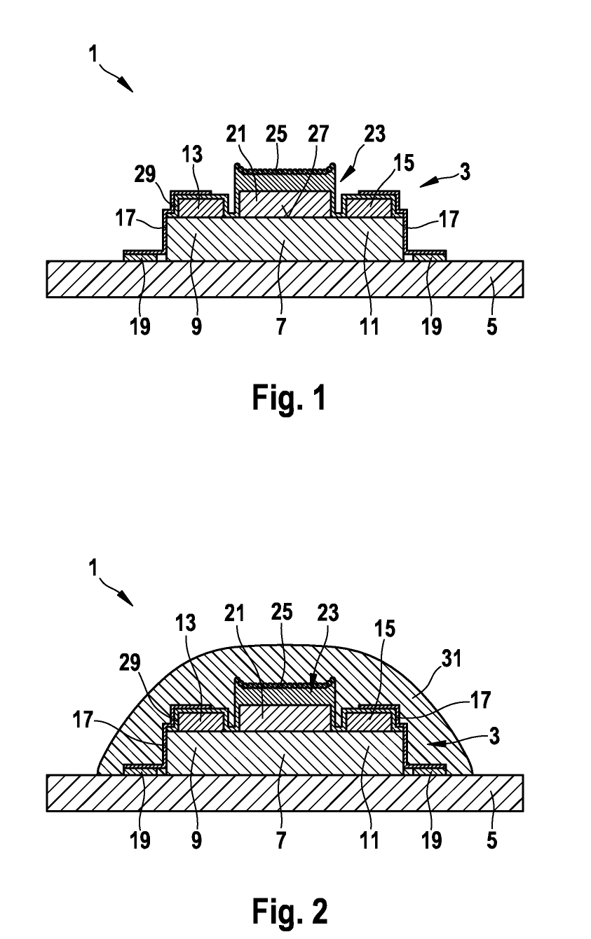

Sensor element 1 depicted in FIG. 1 still has the previously described disadvantages, however, since in particular source electrode 13 and drain electrode 15, as well as contacting means 17 and gas-sensitive coating 25, may be damaged by aggressive media. Furthermore, all surfaces of sensor element 1 may also be damaged mechanically by particles in a gas stream being analyzed, for example an exhaust gas of an internal combustion engine, that flows over the surface of sensor element 1. To remedy this problem, sensitive component 3 is covered with a protective layer. The production of the protective layer according to the present invention is depicted in FIGS. 2 through 4.

A first step in applying the protective layer is depicted in FIG. 2.

In a first step, sensor element 1 is covered with a masking layer 31. The masking layer is made in this case of a material which is thermally decomposable without residue. A polymer is preferably used as the material which is thermally decomposable without residue. As described earlier, suitable polymers are, for example, polyesters, polyethers such as polyethylene glycol, polypropylene glycol, polyethylene oxide, polypropylene oxide, polyacrylates, polyacetates, polyketals, polycarbonates, polyurethanes, polyetherketones, cycloaliphatic polymers, aliphatic polyamides, polyvinyl phenols and epoxy compounds, as well as their co-polymers or ter-polymers. To apply masking layer 31, it is possible, for example, to dissolve or disperse the polymer in a solvent. In this case, the application of the material which is thermally decomposable without residue is followed by a drying step, in order to remove the solvent. Alternatively, it is also possible, however, to use, for example, radiation-curable or heat-curable monomers and/or polymers, which form the masking layer. In that case, after the material for the masking layer is applied, sensor element 1 is irradiated or heated in order to cure the polymers. Suitable radiation-curable or heat-curable monomers and/or polymers are ones that contain, for example, epoxy groups, acrylate groups and/or methacrylate groups as functional groups.

The material which is thermally decomposable without residue for masking layer 31, may be applied using any method with which coating of a three-dimensional element is possible. This is necessary since sensitive component 3 is higher than the carrier substrate on which sensitive component 3 is placed. The application process for masking layer 31 must therefore be able to surmount at least one step. Suitable methods for applying masking layer 31 are, for example, dispensing, ink-jet printing, pad printing, spin coating or dipping. Any other suitable methods that are known to those skilled in the art may also be used to apply the masking layer.

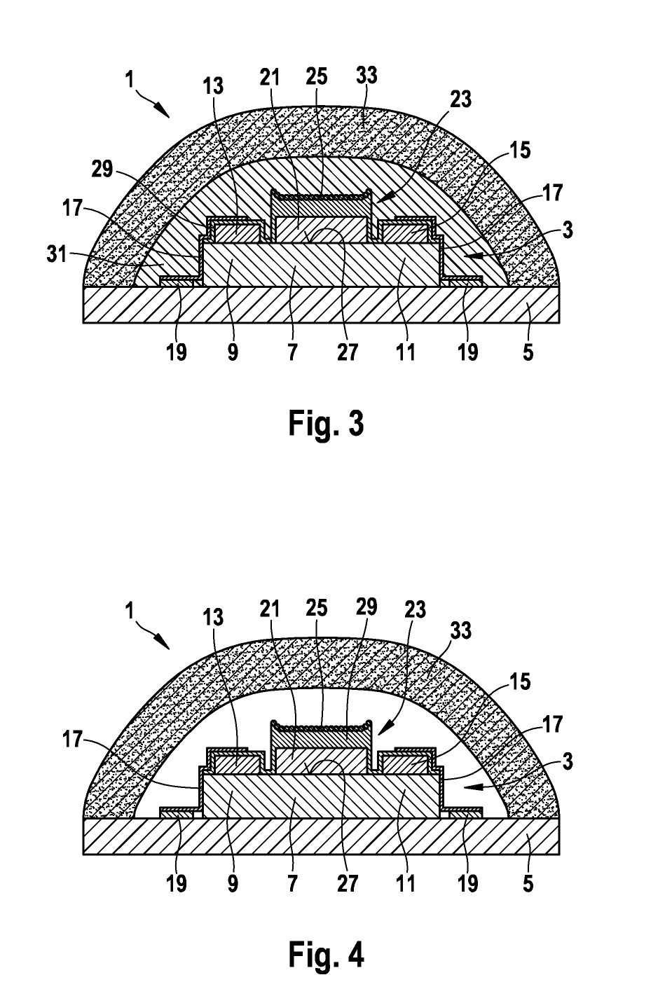

After the masking layer has been applied, a protective layer 33 of a temperature-stable material is applied to masking layer 31. A sensor element 1 with protective layer 33 applied to masking layer 31 is depicted in FIG. 3.

Protective layer 33 is preferably applied using a spraying process, in particular a plasma spraying process. The protective layer 33 applied using the plasma spraying process is preferably characterized by high porosity. Ceramic powders may be used, for example, to produce protective layer 33 or suspensions having ceramic components for a suspension plasma spraying process. An advantage of the plasma spraying process for producing protective layer 33 is that it allows the porosity to be adjusted readily by varying parameters of the plasma spraying process.

A decisive factor is the retention time of the powder or suspension in the plasma. A long retention time results in a completely molten initial substance, and hence a more closed protective layer 33, whereas a short retention time produces an initial substance that is molten merely on the surface, and hence a porous layer on masking layer 31.

In addition, with a plasma spraying method the impact velocity of the particles may also be varied. Impact velocities are typically from 150 m/s up to 450 m/s. Thick layers are also producible, typically between 80 μm and 2 mm, with suspension plasma spraying also thinner layers, for example in the range between 20 μm and 300 μm.

Masking layer 31 makes it possible to avoid damage to sensitive component 3 due to the high impact velocity of the particles during the plasma spraying process.

The plasma spraying method also makes it possible to minimize temperature loads on sensor element 1 when producing protective layer 33. Despite very high temperatures of up to 30,000 K in the plasma, the temperature at sensor element 1 or at sensor body 7 may be kept lower than 400° C. for example. The temperature at sensor element 1 is dependent in particular on the distance of the masked sensor from the plasma source. A separate temperature treatment, in particular a high temperature step for cross-linking the initial substance to the porous layer of protective layer 33, may be dispensed with when using a plasma spraying process, since it is already included in the spraying process. In addition, a plasma spraying process is performable with high reproducibility, and may be integrated well into a production line. Also, a precise coating to produce protective layer 33 is possible by moving sensor element 1 selectively in the plasma.

Using a plasma spraying process, it is possible, for example, to coat an entire sensor tip of a sensor element 1, which includes the entire sensitive component 3, without problems and completely, using a porous protective layer 33. A protective layer 33 of this sort also acts advantageously as thermal shock protection, for example when used in an exhaust tract of an internal combustion engine, and prevents thermal shock loading, for example due to small water droplets striking the heated sensor element 1.

Ceramic materials, for example silicon nitride, silicon oxide, aluminum oxide, zirconium oxide, titanium dioxide or mixtures thereof are usually used as the material for protective layer 33. Preferably, the same material is used from which carrier substrate 5 is also made. The use of a ceramic material for carrier substrate 5 is particularly preferred if sensor element 1 is to be exposed to high temperatures, since the ceramic materials are resistant to high temperatures. In particular, this also makes it possible to avoid damage to carrier substrate 5 in a pyrolysis step that is carried out after the application of protective layer 33 in order to remove masking layer 31. A sensor element 1 from which masking layer 31 has been removed is depicted in FIG. 4.

Masking layer 31 is pyrolyzed by the pyrolysis step, and the resulting gaseous product is removed through porous layer 33. In order to achieve complete and residue-free decomposition of the organic components of masking layer 31, the pyrolysis is preferably performed in air and/or an oxygen-rich or hydrogen-rich atmosphere. To obtain an oxygen-rich atmosphere, it is possible for example, to increase the oxygen content in the air, or alternatively to use pure oxygen. The pyrolysis step during which masking layer 31 is removed may be used at the same time for porous sintering of protective layer 33. In addition, it is possible for the porosity of protective layer 33 to be adjusted by the pyrolysis of masking layer 31. For example, the porosity of protective layer 33 may be further increased thereby. As an alternative to pyrolysis of masking layer 31, it is also possible to carry out a treatment in a low-temperature-guided oxygen plasma. Masking layer 31 is also decomposed in the low-temperature-guided oxygen plasma, and the product of decomposition is removed through protective layer 33.

A sensor element 1 produced according to the method described above may be used especially advantageously to measure a concentration of at least one gas component in an exhaust tract of an internal combustion engine. Particularly preferred is the use of sensor element 1 for selective measurement, i.e., for qualitative and/or quantitative detection of nitrogen oxides, ammonia or hydrocarbons in the exhaust gas. Protective layer 33 according to the present invention, which is formed at a distance from sensitive component 3, makes it possible to protect the complete sensitive component 3 from abrasion, for example from particles contained in the exhaust gas. Sensitive component 3 is protected from chemical components of the exhaust gas, and thus from corrosion, by passivation layer 29.

1-13. (canceled)

14. A method for producing a sensor element having at least one sensitive component, comprising:
(a) applying a masking layer of a material which is thermally decomposable without residue to the sensitive component, wherein the sensitive component is essentially completely covered by the masking layer;
(b) applying a protective layer of a temperature-stable material to the masking layer; and
(c) removing the masking layer by one of pyrolysis or a low-temperature-guided oxygen plasma.

15. The method as recited in claim 14, wherein the material which is thermally decomposable without residue is a thermally decomposable polymer.

16. The method as recited in claim 15, wherein the temperature-stable material is a ceramic material including at least one of silicon nitride, silicon oxide, aluminum oxide, zirconium oxide, and titanium dioxide.

17. The method as recited in claim 16, wherein the material which is thermally decomposable without residue is applied to the sensitive component with a layer thickness in the range of 10 μM to 2 mm.

18. The method as recited in claim 17, wherein the material which is thermally decomposable without residue is applied to the sensitive component by one of dispensing, ink jet printing, pad printing, spin coating or dipping.

19. The method as recited in claim 17, wherein the material which is thermally decomposable without residue is one of dissolved in a solvent or is present as a suspension in a solvent, before being applied to the sensitive component.

20. The method as recited in claim 19, wherein the sensitive component is dried after application of the masking layer of the material which is thermally decomposable without residue, in order to remove the solvent.

21. The method as recited in claim 17, wherein the temperature-stable material for the protective layer is applied by a plasma spraying process.

22. The method as recited in claim 17, wherein the temperature-stable material of the protective layer is sintered during the pyrolysis in step (c).

23. The method as recited in claim 22, wherein the pyrolysis in step (c) is carried out in the presence of an oxygen-rich atmosphere.

24. A sensor element, comprising:
at least one sensitive component; and
a protective layer made of a temperature-stable material and covering the sensitive component;
wherein the sensitive component and the protective layer are placed at a distance from each other.

25. The sensor element as recited in claim 24, wherein the sensitive component is a gas-sensitive field-effect transistor.

26. The sensor element as recited in claim 25, wherein the protective layer made of the temperature-stable material is porous.
